(19) United States
(12) Patent Application Publication
(10) Pub. No.: US 2025/0031319 A1
(43) Pub. Date: Jan. 23, 2025

(54) LAMINATED STRUCTURE, AND METHOD FOR MANUFACTURING LAMINATED STRUCTURE

(71) Applicant: Panasonic Holdings Corporation, Osaka (JP)

(72) Inventors: HIROKI KITAGAWA, Osaka (JP); TAKAYUKI YOSHIDA, Shiga (JP)

(21) Appl. No.: 18/908,875

(22) Filed: Oct. 8, 2024

Related U.S. Application Data
(63) Continuation of application No. PCT/JP2023/005374, filed on Feb. 16, 2023.

(30) Foreign Application Priority Data
Apr. 19, 2022 (JP) 2022-068997

(51) Int. Cl. H05K 3/46; H05K 1/02; H05K 1/03; H05K 1/11; H05K 3/10

(52) U.S. Cl. CPC H05K 3/4626; H05K 1/0274; H05K 1/0306; H05K 1/115; H05K 3/107; H05K 2203/107

(57) ABSTRACT

A laminated structure comprising: a first laminate; a second laminate; and a third laminate, wherein the first laminate, the second laminate, and the third laminate being sequentially laminated, melting points of the first laminate, the second laminate, and the third laminate are different from each other, and the melting point of the second laminate is higher than the melting point of any of the first laminate and the third laminate.

### TECHNICAL FIELD

The present disclosure relates to a laminated structure and a method for manufacturing the laminated structure.

### BACKGROUND ART

PTLs 1 to 3 discloses a technique for producing a laminated structure in which a plurality of members are laminated.

PTL 1 discloses a method for chemically depositing a fluoride of a high melting point metal on a ceramic insulating substrate. PTL 2 discloses a method in which a conductive member is disposed in contact with a ceramic insulating substrate and heated to join the insulating substrate and the conductive member via a predetermined eutectic liquid phase. PTL 3 discloses a method for thermally joining a conductive member having a predetermined shape on a ceramic insulating substrate.

### CITATION LIST

### Patent Literature

PTL 1: Unexamined Japanese Patent Publication No. H03-174382
PTL 2: Unexamined Japanese Patent Publication No. 2013-55264
PTL 3: Unexamined Japanese Patent Publication No. H03-145748

### SUMMARY OF THE INVENTION

A laminated structure of the present disclosure comprises

a first laminate;

a second laminate; and

a third laminate, wherein

the first laminate, the second laminate, and the third laminate being sequentially laminated,

melting points of the first laminate, the second laminate, and the third laminate are different from each other, and

the melting point of the second laminate is higher than the melting point of any of the first laminate and the third laminate.

A method for manufacturing a laminated structure of the present disclosure is

a method for manufacturing a laminated structure formed by sequentially laminating a first laminate, a second laminate, and a third laminate, the method including:

placing the second laminate on the third laminate; and

irradiating a surface portion of the third laminate on the second laminate side with laser light from the second laminate side to melt the surface portion of the third laminate on the second laminate side, and allowing the surface portion that has been melted to enter a recess formed in a surface of the second laminate on the third laminate side.

### BRIEF DESCRIPTION OF THE DRAWINGS

FIG. 1 is a sectional view of a laminated structure according to a first exemplary embodiment.

FIG. 2 is a partial sectional view of the laminated structure according to the first exemplary embodiment.

FIG. 3 is a diagram illustrating a step of joining a second laminate and a third laminate in a manufacturing step for the laminated structure according to the first exemplary embodiment.

FIG. 4 is a diagram illustrating a step of joining a first laminate and the second laminate in a manufacturing step for the laminated structure according to the first exemplary embodiment.

FIG. 5 is a sectional view of a laminated structure according to a second exemplary embodiment.

FIG. 6 is a diagram illustrating a step of joining a first laminate and the second laminate in a manufacturing step for the laminated structure according to the second exemplary embodiment.

FIG. 7 is a sectional view of a laminated structure according to a third exemplary embodiment.

FIG. 8 is a diagram illustrating a step of determining a formation position of a pattern portion in a manufacturing step for the laminated structure according to the third exemplary embodiment.

FIG. 9A is a diagram illustrating a step of partially joining a second laminate and a third laminate in a manufacturing step for the laminated structure according to the third exemplary embodiment.

FIG. 9B is a diagram illustrating a formation region of the pattern portion.

FIG. 10 is a diagram illustrating a step of forming a circuit pattern in a manufacturing step for the laminated structure according to the third exemplary embodiment.

FIG. 11 is a diagram illustrating a step of reinforcing the joining between the second laminate and the third laminate in a manufacturing step for the laminated structure according to the third exemplary embodiment.

FIG. 12 is a diagram illustrating a step of joining a first laminate and the second laminate in a manufacturing step for the laminated structure according to the third exemplary embodiment.

FIG. 13 is a sectional view of a laminated structure according to a fourth exemplary embodiment.

FIG. 14 is a diagram illustrating a fourth laminate in which a through hole is formed.

FIG. 15 is a diagram illustrating a step of forming the fourth laminate on a fifth laminate in a manufacturing step for the laminated structure according to the fourth exemplary embodiment.

FIG. 16 is a diagram illustrating a step of joining two circuit boards in a manufacturing step for the laminated structure according to the fourth exemplary embodiment.

FIG. 17 is a diagram illustrating a step of joining a top circuit board to a multiple structure in a manufacturing step for the laminated structure according to the fourth exemplary embodiment.

### DESCRIPTION OF EMBODIMENT

Complicated steps are required to perform the methods of PTLs 1 and 2. A large number of devices are required, or a large device is required to perform the method of PTL 3.

An object of the present disclosure is to provide a laminated structure and a method for manufacturing the laminated structure that can easily manufacture a laminated structure in which a plurality of members are laminated with a small number of devices.

Exemplary embodiments and modifications according to the present disclosure will be described below with reference to the drawings.

### First Exemplary Embodiment

### <Laminated Structure>

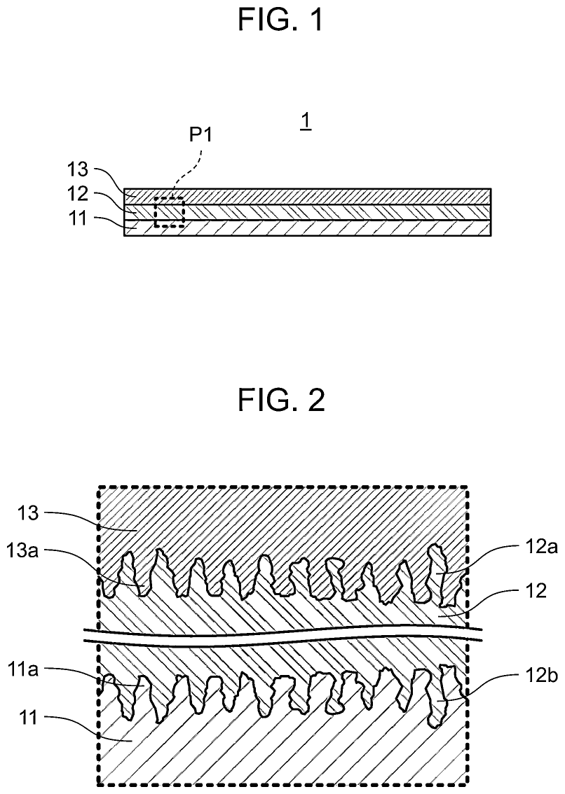

FIG. 1 is a sectional view of laminated structure 1 according to a first exemplary embodiment. FIG. 2 is a partial sectional view of the P1 portion in laminated structure 1 illustrated in FIG. 1.

Laminated structure 1 includes first laminate 11, second laminate 12, and third laminate 13 that are sequentially laminated.

First laminate 11 and third laminate 13 are formed of, for example, a conductive material. Second laminate 12 is formed of, for example, an insulating material.

Second laminate 12 desirably has as high thermal conductivity as possible. Second laminate 12 is formed of, for example, aluminum nitride, and has a thermal conductivity of about 200 W/(m·K). When laminated structure 1 is used as a heat dissipation device, second laminate 12 desirably has as high thermal conductivity as possible. When second laminate 12 is made of aluminum nitride, melting point T12 of second laminate 12 is about 2200° C.

Third laminate 13 is formed of, for example, copper. When third laminate 13 is formed of copper, melting point T13 of third laminate 13 is about 1084° C.

First laminate 11 is formed of a material different from the material of third laminate 13. First laminate 11 is formed of, for example, aluminum. When first laminate 11 is formed of aluminum, melting point T11 of first laminate 11 is about 660° C.

First laminate 11 and second laminate 12 are welded. As illustrated in FIG. 2, at the joining interface between first laminate 11 and second laminate 12, irregularities formed on their surfaces mesh with each other.

Second laminate 12 and third laminate 13 are welded. At the joining interface between second laminate 12 and third laminate 13, the irregularities formed on their surfaces mesh with each other.

In the present exemplary embodiment, melting points T11, T12, T13 of first laminate 11, second laminate 12, and third laminate 13 have a relationship of T12>T13>T11.

First laminate 11 may be formed of a copper material like third laminate 13.

However, melting point T11 of first laminate 11 is adjusted to be lower than melting point T13 of third laminate 13. For example, the melting point of the copper material can be made different by adding an additive. The melting point of the copper material can be adjusted by changing the amount of the additive or the type of the additive.

For example, laminated structure 1 is used in a heat dissipation device that dissipates heat of a semiconductor element disposed above third laminate 13 (conductive material) to first laminate 11 (conductive material) side via second laminate 12 (insulating material).

### <Manufacturing Method>

Next, a method for manufacturing laminated structure 1 will be described. Hereinafter, an example in which first laminate 11 is made of aluminum, second laminate 12 is made of aluminum nitride ceramic, and third laminate 13 is made of copper will be described.

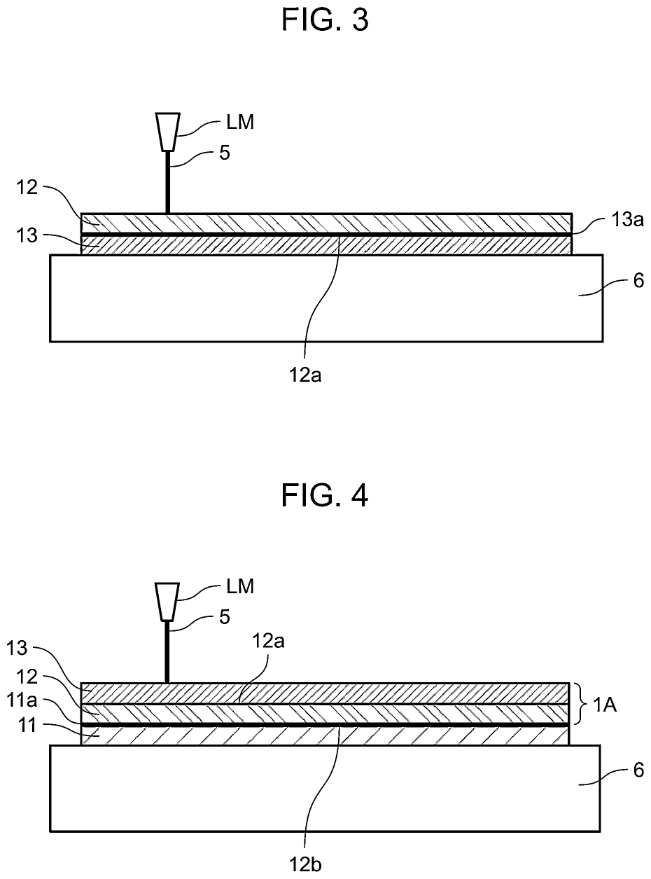

FIG. 3 is a diagram illustrating a step of joining second laminate 12 and third laminate 13. FIG. 4 is a diagram illustrating a step of joining first laminate 11 and second laminate 12. In the present exemplary embodiment, as illustrated in FIGS. 3 and 4, laminated structure 1 is manufactured by using laser emission device LM that emits laser light 5.

As laser light 5, laser light having a wavelength at which the absorptivity of second laminate 12 and third laminate 13 is high and the absorptivity of first laminate 11 is lower than that of third laminate 13 by a predetermined value or more is used. In other words, the wavelength of laser light 5 is set such that the absorptivity of first laminate 11 is lower than that of third laminate 13 by a predetermined value or more. The predetermined value is, for example, about 50%.

In the present exemplary embodiment, laser light 5 has a wavelength of more than or equal to 400 nm and less than or equal to 600 nm. Thus, the laser light 5 is easily absorbed by second laminate 12 (aluminum nitride ceramic) and third laminate 13 (copper). More specifically, the absorptivity of first laminate 11, second laminate 12, and third laminate 13 with respect to laser light 5 decrease in the order of second laminate 12, third laminate 13, and first laminate 11.

The blue wavelength band (more than or equal to 430 nm and less than or equal to 490 nm) and the green wavelength band (more than or equal to 490 nm and less than or equal to 550 nm) belong to the wavelength band of more than or equal to 400 nm and less than or equal to 600 nm. This wavelength band is a wavelength band shorter than ultraviolet rays.

Aluminum nitride ceramic and copper have high absorptivity with respect to laser light having a short wavelength. On the other hand, since laser light in a wavelength band shorter than ultraviolet rays has high output, laser emission device LM having high performance is required to emit the laser light.

In the present exemplary embodiment, since laser light 5 having a wavelength of more than or equal to 400 nm and less than or equal to 600 nm is used, laminated structure 1 can be easily manufactured even when laser emission device LM does not have the performance capable of outputting a high-power laser light.

### (1) Joining of Second Laminate and Third Laminate

First, third laminate 13 is placed on table 6. Table 6 is formed of, for example, a material having a melting point high enough not to melt at least at the time of laser irradiation, and having a thermal conductivity lower than that of any of first laminate 11, second laminate 12, and third laminate 13.

Next, second laminate 12 is placed on third laminate 13. Then, in a state where second laminate 12 is pressed against third laminate 13, laser light 5 is emitted from second laminate 12 side. In laser emission device LM, the intensity of laser light 5 is set to such an extent that only third laminate 13 melts out of second laminate 12 and third laminate 13.

Second laminate 12 is heated by laser light 5. The heat generated at second laminate 12 is transferred to surface portion 13a of third laminate 13. Second laminate 12, having a larger absorptivity with respect to laser light 5 than third laminate 13, easily generates heat.

Since melting point T13 of third laminate 13 is lower than melting point T12 of second laminate 12, surface portion 13a of third laminate 13 melts but second laminate 12 does not melt. Then, melted surface portion 13a enters a recess formed in main surface 12a of second laminate 12 (see FIG. 2). Thereafter, as the temperature of surface portion 13a decreases, surface portion 13a becomes a solid state, and surface portion 13a meshes with the irregular portion of main surface 12a of second laminate 12. As a result, second laminate 12 and third laminate 13 are joined. Laminated portion 1A of second laminate 12 and third laminate 13 is thus formed (see FIG. 4).

### (2) Joining of First Laminate 11 and Second Laminate 12

Next, as illustrated in FIG. 4, first laminate 11 is placed on table 6, and laminated portion 1A is placed thereon such that second laminate 12 and first laminate 11 are in contact with each other.

Next, in a state where second laminate 12 is pressed against first laminate 11, laser light 5 is emitted from third laminate 13 side. In laser emission device LM, the intensity of laser light 5 is set to such an extent that only first laminate 11 melts out of first laminate 11, second laminate 12, and third laminate 13.

Third laminate 13 is heated by laser light 5. The heat generated in third laminate 13 is transferred to first laminate 11 via second laminate 12. Second laminate 12, having a larger absorptivity with respect to laser light 5 than third laminate 13, easily generates heat.

Since melting point T11 of first laminate 11 is lower than melting points T12, T13 of second laminate 12 and third laminate 13, surface portion 11a of first laminate 11 melts but second laminate 12 and third laminate 13 do not melt. Then, melted surface portion 11a enters a recess formed in main surface 12b of second laminate 12 (see FIG. 2). Thereafter, as the temperature of surface portion 11a decreases, surface portion 11a becomes a solid state, and surface portion 11a meshes with the irregular portion of main surface 12b of second laminate 12. As a result, first laminate 11 and second laminate 12 are joined. In this manner, laminated structure 1 in which first laminate 11, second laminate 12, and third laminate 13 are joined is manufactured.

Laminated structure 1 according to the present exemplary embodiment is formed by sequentially laminating first laminate 11, second laminate 12, and third laminate 13, and the melting points of first laminate 11, second laminate 12, and third laminate 13 are different from each other. Melting point T12 of second laminate 12 is higher than any of melting points T11, T13 of first laminate 11 and third laminate 13.

That is, laminated structure 1 has a structure that can be produced by welding using laser light 5 while pressing second laminate 12 against each of first laminate 11 and third laminate 13 using laser light 5. Thus, it is possible to easily manufacture a laminated structure in which a plurality of members are laminated with a small number of devices.

In addition, since the welding can be performed using laser light 5, surface portions 11a, 13a of first laminate 11 and third laminate 13 can be welded in such a manner as to mesh with the irregularities of the main surfaces 12b, 12a of second laminate 12. That is, a large adhesion area can be secured, and the adhesion between the laminates can be increased.

In the present exemplary embodiment, second laminate 12 is formed of an insulating material, and first laminate 11 and third laminate 13 are formed of a conductive material.

Thus, laminated structure 1 of the present exemplary embodiment can be used as, for example, a heat dissipation device that dissipates heat of a semiconductor element disposed above third laminate 13 (conductive material) to first laminate 11 (conductive material) side via second laminate 12 (insulating material).

In the present exemplary embodiment, second laminate 12 is formed of aluminum nitride ceramic. First laminate 11 is formed of an aluminum material, and third laminate 13 is formed of a copper material. In this manner, melting point T11 of first laminate 11, melting point T12 of second laminate 12, and melting point T13 of third laminate 13 satisfy the relationship of T12>T13>T11.

Alternatively, first laminate 11 and third laminate 13 are formed of copper materials having different melting points. With this configuration, melting point T12 of second laminate 12 is made higher than melting point T11 of first laminate 11 and melting point T13 of third laminate 13, and a difference is provided between melting points of first laminate 11 and third laminate 13.

In addition, the absorptivity of third laminate 13 with respect to laser light 5 in the predetermined wavelength band is larger than the absorptivity of first laminate 11. Thus, when laminated portion 1A of second laminate 12 and third laminate 13 and first laminate 11 are welded using laser light 5, the heat generated in third laminate 13 can be effectively transmitted to first laminate 11 via second laminate 12 by irradiating third laminate 13 with laser light 5.

The predetermined wavelength band is more than or equal to 400 nm and less than or equal to 600 nm. That is, laser light 5 having a wavelength band shorter than ultraviolet rays and easily absorbed by second laminate 12 and third laminate 13 is used. Thus, it is possible to efficiently generate laminated structure 1 without using a high-performance laser emission device.

In the method for manufacturing laminated structure 1 according to the present exemplary embodiment, second laminate 12 is placed on third laminate 13, and surface portion 13a of third laminate 13 is melted by irradiating laser light 5 from second laminate 12 side, and melted surface portion 13a is made to enter the recess formed in main surface 12a of second laminate 12.

Thus, laminated structure 1 can be easily manufactured by welding the laminates to each other with a small number of devices. In addition, since surface portion 13a of third laminate 13 is made to enter the recess formed in main surface 12a of second laminate 12, it is possible to manufacture laminated structure 1 in which the laminates are welded to each other with a wide adhesion area and high adhesion.

Laminated portion 1A of second laminate 12 and third laminate 13 is placed on first laminate 11 such that second laminate 12 is in contact with first laminate 11, surface portion 11a of first laminate 11 is melted by irradiating laser light 5 from third laminate 13 side, and melted surface portion 11a is made to enter a recess formed on main surface 12b of second laminate 12.

Thus, laminated structure 1 in which second laminate 12 is welded to first laminate 11 and third laminate 13 with high adhesion while securing a wide adhesion area is generated. For example, when a semiconductor element is disposed on third laminate 13, laminated structure 1 functions as a heat dissipation device that smoothly dissipates heat generated by the semiconductor element to first laminate 11 via second laminate 12.

### Second Exemplary Embodiment

Hereinafter, a second exemplary embodiment will be described mainly for differences from the first exemplary embodiment.

### <Laminated Structure>

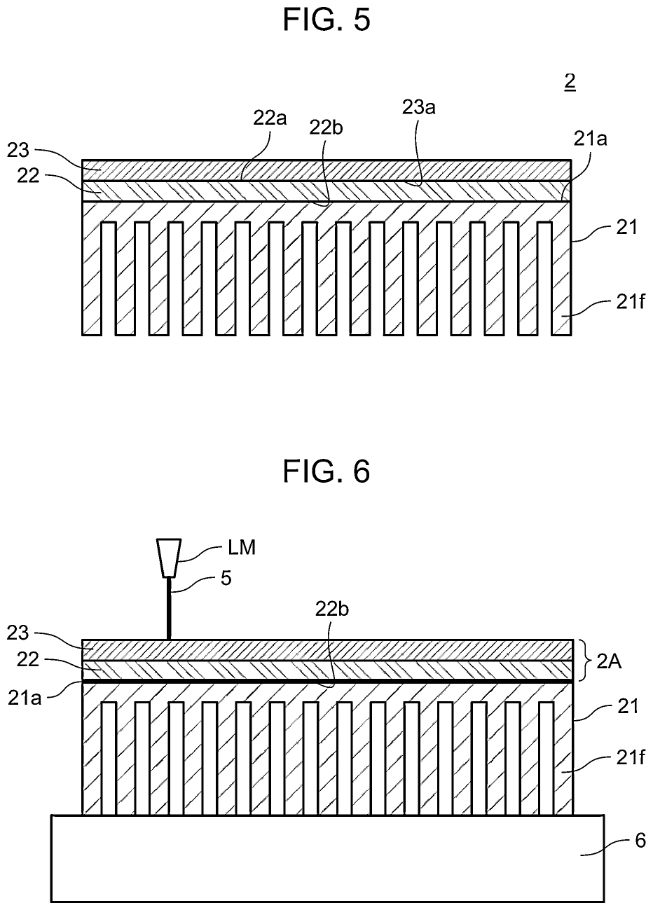

FIG. 5 is a sectional view of laminated structure 2 according to the second exemplary embodiment.

Laminated structure 2 includes first laminate 21, second laminate 22, and third laminate 23 that are sequentially laminated. Second laminate 22 and third laminate 23 have the same configuration and function as second laminate 12 and third laminate 13 of the first exemplary embodiment, respectively.

First laminate 21 is a heat dissipation member having a heat dissipation structure for releasing heat. First laminate 21 includes, for example, a plurality of fins 21f as the heat dissipation structure. First laminate 21 may be a heat dissipation member having a block shape without having fins 21f.

In the present exemplary embodiment, laminated structure 2 is a heat dissipation device in which the heat of a semiconductor element disposed above third laminate 13 is transmitted to first laminate 11 via second laminate 22 and released by first laminate 11 having a heat dissipation function.

First laminate 21 is welded to second laminate 22. At the joining interface between first laminate 21 and second laminate 22, as in the first exemplary embodiment, the irregularities formed on their surfaces mesh with each other.

First laminate 21 is formed of the same material as first laminate 11 of the first exemplary embodiment. Thus, melting points T21, T22, and T23 of first laminate 21, second laminate 22, and third laminate 23 have a relationship of T22>T23>T21. Second laminate 22 and third laminate 23 have a higher absorptivity with respect to laser light 5 than first laminate 21.

### <Manufacturing Method>

Next, a method for manufacturing laminated structure 2 will be described. FIG. 6 is a diagram illustrating a step of joining first laminate 21 and second laminate 22.

First, second laminate 22 is welded to third laminate 23. Laminated portion 2A of third laminate 23 and second laminate 22 is thus formed. This step is the same as in the first exemplary embodiment.

Next, first laminate 21 is placed on table 6 such that fins 21f are in contact with table 6, and laminated portion 2A is placed thereon such that second laminate 22 and first laminate 21 are in contact with each other.

Next, in a state where second laminate 22 is pressed against first laminate 21, laser light 5 is emitted from third laminate 23 side. In laser emission device LM, the intensity of laser light 5 is set to such an extent that only first laminate 21 melts out of first laminate 21, second laminate 22, and third laminate 23.

Third laminate 23 is heated by laser light 5. The heat generated in third laminate 23 is transferred to first laminate 21 via second laminate 22. Second laminate 22, having a larger absorptivity with respect to laser light 5 than third laminate 23, easily generates heat.

Since melting point T21 of first laminate 21 is lower than melting points T22, T23 of second laminate 22 and third laminate 23, surface portion 21a of first laminate 21 melts but second laminate 12 and third laminate 13 do not melt. Then, melted surface portion 21a enters a recess formed in main surface 22b of second laminate 22. Thereafter, as the temperature of surface portion 21a decreases, surface portion 21a becomes a solid state, and surface portion 21a meshes with the irregular portion of main surface 22b of second laminate 22. As a result, first laminate 21 and second laminate 22 are joined. In this manner, laminated structure 2 in which first laminate 21, second laminate 22, and third laminate 23 are joined is manufactured.

According to the present exemplary embodiment, the same effects as those of the first exemplary embodiment can be obtained.

In the present exemplary embodiment, melting point T21 of first laminate 21 is lower than melting point T23 of third laminate 23, and first laminate 21 has a heat dissipation structure.

Thus, only first laminate 21 can be melted using laser light 5 after third laminate 23 and second laminate 22 are welded to each other, and thus second laminate 22 can be easily welded to first laminate 21 with a wide adhesion area and high adhesion.

In addition, for example, first laminate 21 has a heat dissipation structure such as a plurality of fins 21f. That is, first laminate 21 has a structure that is hardly welded to second laminate 22 by a method called thermocompression bonding. However, according to the present exemplary embodiment, using the laser light 5 makes it possible to easily weld second laminate 12 to first laminate 21 with a wide adhesion area and high adhesion.

### <Effects as Heat Dissipation Device>

Advantages of applying laminated structure 2 and the method for manufacturing laminated structure 2 according to the present exemplary embodiment to a device on which a high-output semiconductor element is mounted (hereinafter, referred to as “semiconductor-mounted apparatus”) will be described.

A high-output semiconductor element is mounted on apparatuses such as two-wheeled vehicles, four-wheeled vehicles, unmanned aerial vehicles, home energy saving devices, laser processing devices, and communication devices used in data centers. Since power consumption in the high-output semiconductor element is large, a heat dissipation member that dissipates heat of the high-output semiconductor element is disposed in the semiconductor-mounted apparatus.

In a semiconductor-mounted apparatus, it is necessary to ensure insulation between a circuit pattern connected to the high-output semiconductor element and the heat dissipation member. In particular, when the circuit pattern is formed using a relatively thick metal foil, it is necessary to further ensure insulation between the heat dissipation device and the circuit pattern. Thus, an insulating substrate is disposed between the heat dissipation device and the circuit pattern.

It is necessary to increase the thermal conductivity between the insulating substrate and the heat dissipation device to effectively dissipate the heat of the high-output semiconductor element. However, since the heat dissipation device has a heat dissipation structure, the insulating substrate and the heat dissipation device cannot be brought into close contact with each other through thermocompression bonding. That is, it has not been possible to directly bring the insulating substrate and the heat dissipation device into close contact with each other while securing a wide adhesion area, and a desired thermal conductivity has not been obtained.

Thus, a thermal interface material (TIM) such as grease or a heat dissipation sheet containing a highly thermally conductive filler has conventionally been provided between the insulating substrate and the heat dissipation device. However, sufficient thermal conductivity has not been able to be secured.

In laminated structure 2 according to the present exemplary embodiment, first laminate 21 is formed of a material having a melting point lower than that of third laminate 23. Thus, when laminated structure 2 is applied to a semiconductor-mounted device as a heat dissipation device, surface portion 21a of first laminate 21 (heat dissipation member) can be melted and welded to second laminate 22 (insulating substrate) by using laser light 5, which makes it possible to widen an adhesion area between first laminate 21 (heat dissipation member) and second laminate 22 (insulating substrate). Further, first laminate 21 (heat dissipation member) is directly joined to second laminate 22 (insulating substrate) without providing another member between first laminate 21 (heat dissipation member) and second laminate 22 (insulating substrate).

Thus, in laminated structure 2, high thermal conductivity is secured between second laminate 22 (insulating substrate) and first laminate 21 (heat dissipation member) while securing insulation between the high-output semiconductor element on third laminate 23 (circuit pattern) and first laminate 21 (heat dissipation member).

PTLs 1 to 3 disclose a method of directly joining an insulating substrate and a conductive member, but the method has problems in terms of process complexity and the number and scale of necessary devices.

In laminated structure 2, first laminate 21 and second laminate 22, and second laminate 22 and third laminate 23 can be directly and easily welded only by irradiation with laser light 5 without requiring complicated steps, a large number of devices, or a large-sized device.

### Third Exemplary Embodiment

Hereinafter, a third exemplary embodiment will be described mainly for differences from the first exemplary embodiment.

### <Laminated Structure>

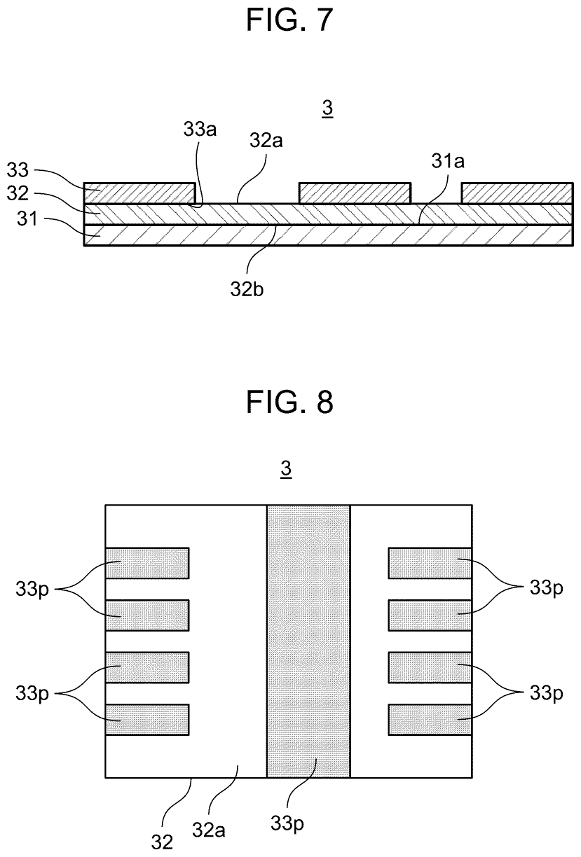

FIG. 7 is a sectional view of laminated structure 3 according to the third exemplary embodiment. FIG. 8 is a plan view of laminated structure 3.

Laminated structure 3 includes first laminate 31, second laminate 32, and third laminate 33 that are sequentially laminated. Laminated structure 3 is an electric circuit board. First laminate 31 and third laminate 33 are formed on both surfaces of second laminate 32 which is an insulating substrate. First laminate 31 forms a ground pattern of the electric circuit board, and third laminate 33 forms a circuit pattern of the electric circuit board.

First laminate 31 and second laminate 32 have the same configuration and function as first laminate 11 and second laminate 12 of the first exemplary embodiment, respectively.

In the present exemplary embodiment, as illustrated in FIG. 8, third laminate 33 has a plurality of pattern portions 33p. Pattern portion 33p is a metal foil such as a copper foil.

Third laminate 33 is formed of, for example, copper or a copper material to which an additive is added, in the same manner as the third laminate 13 of the first exemplary embodiment.

At the joining interface between second laminate 32 and third laminate 33, the irregularities formed on their surfaces mesh with each other.

In the present exemplary embodiment, melting points T31, T32, T33 of first laminate 31, second laminate 32, and third laminate 33 have a relationship of T32>T33>T31. Second laminate 32 and third laminate 33 have a higher absorptivity with respect to laser light 5 than first laminate 31.

### <Manufacturing Method>

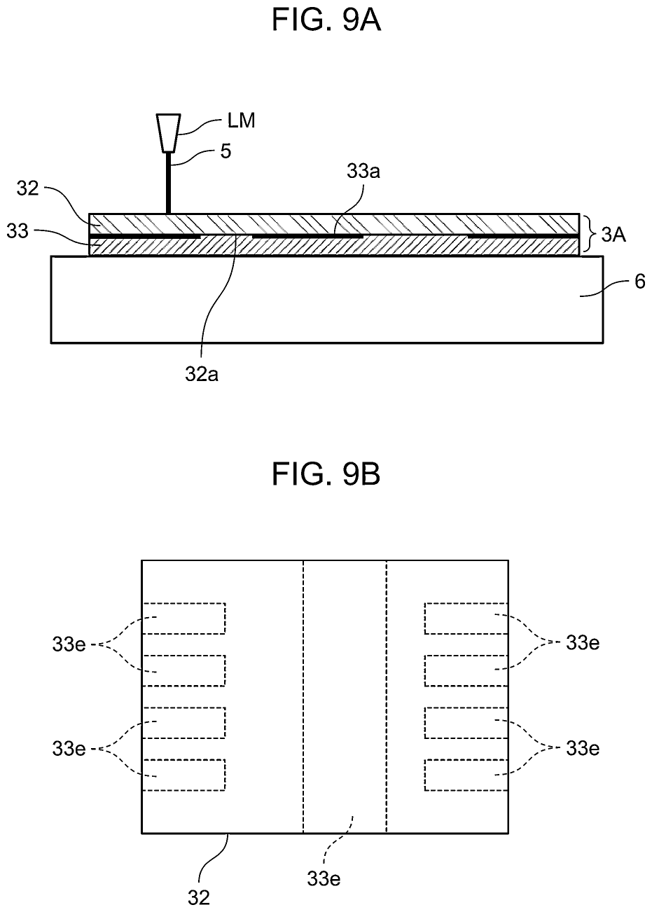

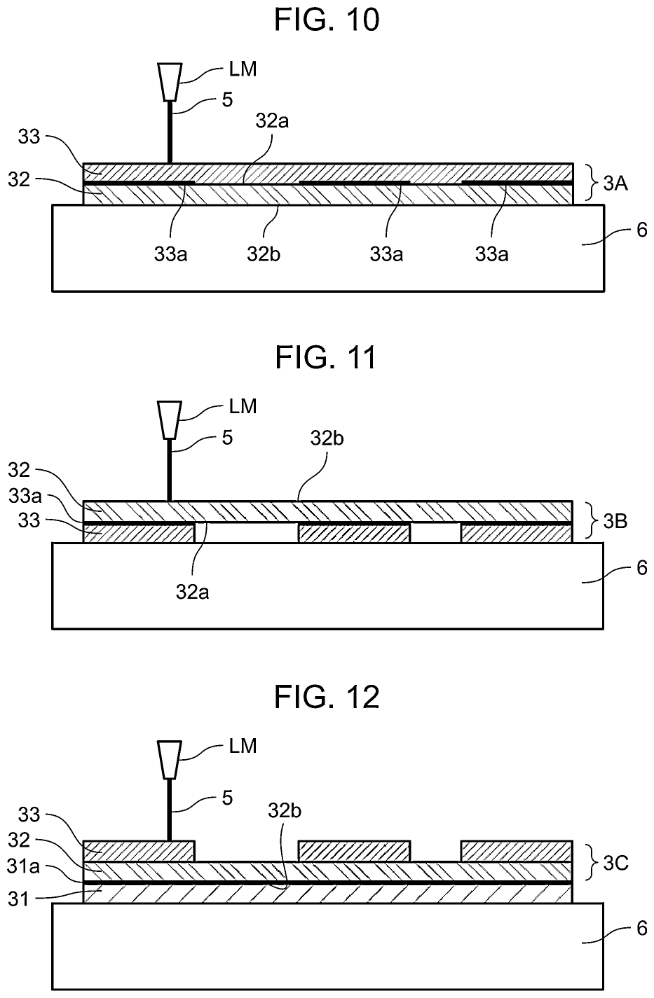

Next, a method for manufacturing laminated structure 3 will be described. FIG. 9A is a diagram illustrating a step of partially joining second laminate 32 and third laminate 33. FIG. 9B is a diagram illustrating a formation region of pattern portion 33p. FIG. 10 is a diagram illustrating a step of forming a circuit pattern. FIG. 11 is a diagram illustrating a step of reinforcing the joining between second laminate 32 and third laminate 33. FIG. 12 is a diagram illustrating a step of joining first laminate 31 and second laminate 32.

### (1) Formation of Circuit Pattern

First, as illustrated in FIG. 9A, third laminate 33 having a plate shape is placed on table 6, and in a state where second laminate 32 is pressed against third laminate 33, a region 33e (see FIG. 9B) corresponding to a predetermined circuit pattern (hereinafter, the region is referred to as “pattern region”) is irradiated with laser light 5 from second laminate 32 side. FIG. 9B illustrates a plan view of second laminate 32 placed on third laminate 33. In laser emission device LM, the intensity of laser light 5 is set to such an extent that only third laminate 33 melts out of second laminate 32 and third laminate 33.

Second laminate 32 is heated by laser light 5, and the heat generated in second laminate 32 is transmitted to surface portion 33a of pattern region 33e of third laminate 33. Second laminate 32, having a larger absorptivity with respect to laser light 5 than third laminate 33, easily generates heat.

Since melting point T33 of third laminate 33 is lower than melting point T32 of second laminate 32, surface portion 33a of third laminate 33 melts but second laminate 32 does not melt. Then, melted surface portion 33a enters a recess formed in main surface 32a of second laminate 32. Thereafter, as the temperature of surface portion 33a decreases, surface portion 33a becomes a solid state, and surface portion 33a meshes with the irregular portion of main surface 32a of second laminate 32. As a result, in the region corresponding to pattern region 33e, surface portion 33a meshes with the irregular portion of main surface 32a, and laminated portion 3A in which third laminate 33 is partially welded to second laminate 32 is formed.

Next, as illustrated in FIG. 10, laminated portion 3A is placed again on table 6 such that second laminate 32 is in contact with table 6. Then, a portion other than the portion corresponding to pattern region 33e in third laminate 33 is removed through irradiation with laser light 5 from third laminate 33 side. As a result, third laminate 33 becomes a circuit pattern layer. Here, in laser emission device LM, the intensity of laser light 5 is set so as to have an intensity capable of cutting off third laminate 33. Also when a part of third laminate 33 is removed, laser light in a wavelength band of more than or equal to 400 nm and less than or equal to 600 nm is used. That is, third laminate 33, which is a circuit pattern layer, is formed using laser emission device LM not having very high performance.

Third laminate 33, which is a circuit pattern, is thus formed on main surface 32a of second laminate 32. Hereinafter, second laminate 32 on which third laminate 33 is formed is referred to as laminated portion 3B.

Next, as illustrated in FIG. 11, laminated portion 3B is placed again on table 6 such that third laminate 33 is in contact with table 6. Then, laser light 5 is emitted from second laminate 32 side. In laser emission device LM, the intensity of laser light 5 is set to such an extent that only third laminate 33 melts out of second laminate 32 and third laminate 33.

Second laminate 32 is heated by laser light 5. The heat generated in second laminate 32 is transmitted to surface portion 33a of third laminate 33, and surface portion 33a of third laminate 33 melts but second laminate 32 does not melt. Surface portion 33a further meshes with the irregular portion of main surface 32a. Thereafter, the temperature of surface portion 33a decreases, and surface portion 33a becomes a solid state. As a result, second laminate 32 and third laminate 33 are more firmly joined. Laminated portion 3C in which second laminate 32 and third laminate 33 are firmly joined is formed.

### (2) Joining of First Laminate 31 and Second Laminate 32

Next, as illustrated in FIG. 12, first laminate 31 is placed on table 6, and laminated portion 3C is placed thereon such that first laminate 31 and second laminate 32 are in contact with each other. In a state where second laminate 32 is pressed against first laminate 31, laser light 5 is emitted from third laminate 33 side. Here, in laser emission device LM, the intensity of laser light 5 is set to such an extent that only first laminate 31 melts out of first laminate 31, second laminate 32, and third laminate 33. The joining between second laminate 32 and first laminate 31 is the same as the joining between first laminate 11 and second laminate 12 in the first exemplary embodiment.

Laminated structure 3 is thus formed.

As described above, in the step of removing a part of third laminate 33 having a plate shape to form third laminate 33 that is a circuit pattern, laser light 5 in the wavelength band of more than or equal to 400 nm and less than or equal to 600 nm is used in the same manner as in the step of joining second laminate 32 to first laminate 31. Thus, laminated structure 3 can be formed with simple control.

In the present exemplary embodiment, third laminate 33 is a circuit pattern layer. Thus, laminated structure 3 functions as an electric circuit board.

In the present exemplary embodiment, a part of third laminate 33 is removed such that third laminate 33 has a predetermined circuit pattern through irradiation with laser light 5.

This makes it possible to form laminated structure 3 having a circuit pattern layer. In addition, using laser light 5 not only for welding but also for forming third laminate 33 makes it possible to easily form laminated structure 3.

### Fourth Exemplary Embodiment

Hereinafter, a fourth exemplary embodiment will be described mainly for differences from the third exemplary embodiment.

### <Laminated Structure>

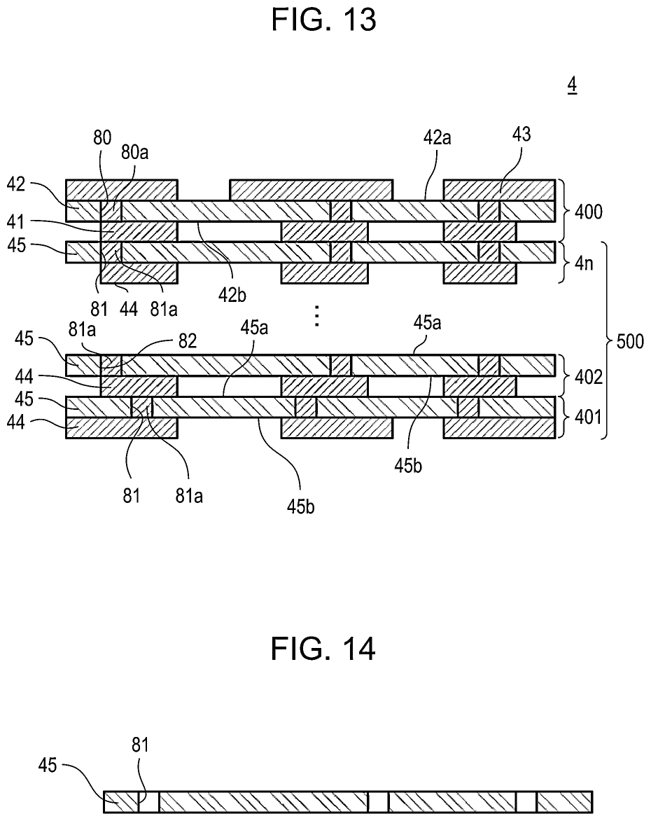

FIG. 13 is a sectional view of laminated structure 4 according to the fourth exemplary embodiment.

Laminated structure 4 is a multilayer circuit board in which a plurality of electric circuit boards are laminated. Laminated structure 4 includes top circuit board 400 and n (n is an integer) pieces of circuit boards 401 to 4n, and circuit board 401, circuit board 402, . . . , circuit board 4n, and top circuit board 400 are laminated in this order. The n pieces of circuit boards 401 to 4n are laminated to form multiple structure 500.

Top circuit board 400 includes first laminate 41, second laminate 42, and third laminate 43 that are sequentially laminated. First laminate 41 and third laminate 43, which are circuit pattern layers, are formed on both surfaces of second laminate 42, which is an insulating substrate.

The irregularities formed on the surfaces of first laminate 41 and second laminate 42 mesh with each other at the joining interface, and in the same manner, the irregularities formed on the surfaces of second laminate 42 and third laminate 43 mesh with each other at the joining interface.

Through hole 80 penetrating from one main surface 42a to the other main surface 42b is formed in second laminate 42. Conductive via 80a is disposed inside through hole 80.

First laminate 41 and third laminate 43 are electrically connected to conductive via 80a.

Circuit boards 401 to 4n include fourth laminate 44 and fifth laminate 45. Fourth laminate 44, which is a circuit pattern layer, is formed on one surface of fifth laminate 45, which is an insulating substrate. At the joining interface between fourth laminate 44 and fifth laminate 45, the irregularities formed on their surfaces mesh with each other. In the same manner, at the joining interface between fourth laminate 44 of circuit boards 402 to 4n and fifth laminate 45 of circuit boards 401 to 4n-1 one stage below, the irregularities formed on their surfaces mesh with each other.

Through hole 81 penetrating from one main surface 45a to the other main surface 45b is formed in fifth laminate 45. Conductive via 81a is disposed inside through hole 81, and fourth laminate 44 is connected to conductive via 81a.

Fourth laminate 44 of circuit boards 402 to 4n is connected to fourth laminate 44 of circuit boards 401 to 4n-1 one stage below via conductive via 81a of the circuit boards.

First laminate 41 of top circuit board 400 is disposed on fifth laminate 45 of circuit board 4n. At the joining interface between first laminate 41 of top circuit board 400 and fifth laminate 45 of circuit board 4n, the irregularities formed on their surfaces mesh with each other. First laminate 41 of top circuit board 400 is connected to conductive via 81a of fifth laminate 45 of circuit board 4n.

The materials of second laminate 42 of top circuit board 400 and fifth laminate 45 of circuit boards 401 to 4n have the same structure and function as those of second laminate 32 of the third exemplary embodiment.

First laminate 41, third laminate 43, and fourth laminate 44 have the same structure and function as those of third laminate 33 of the third exemplary embodiment, and these laminates are formed of, for example, copper or a copper material obtained by adding an additive to copper. The amount of the additive and the type of the additive are adjusted such that the melting points of first laminate 41, third laminate 43, and fourth laminate 44 satisfy a predetermined relationship described later.

Conductive via 80a of second laminate 42 of top circuit board 400 are formed of the same material as first laminate 41. Conductive via 81a of circuit boards 401 to 4n is formed of, for example, the same material as fourth laminate 44 of the same circuit board.

Hereinafter, the relationship between the melting points of the laminates and the conductive vias of laminated structure 4 will be described. When the melting points of first laminate 41, second laminate 42, and third laminate of top circuit board 400 are denoted by T41, T42, T43, the melting point of conductive via 80a of second laminate 42 of top circuit board 400 is denoted by T80, the melting points of fourth laminate 44 of circuit boards 401 to 4n are denoted by TL1, TL2, . . . , TLn, respectively, and the melting points of through holes 81 of fifth laminate 45 of circuit boards 401 to 4n are denoted by TM1, TM2, . . . , TMn, these melting points have a relationship represented by Formula (1) shown below.

$$T 43 > TL 1 = TM 1 > TL 2 = TM 2 > … > TLn = TMn > T 41 \qquad ( 1 )$$

The melting point of fourth laminate 44 of circuit boards 401 to 4n is lower as the disposed position becomes closer to second laminate 42.

Each melting point of fifth laminate 45 of circuit boards 401 to 4n is substantially equal to melting point T42 of second laminate 42, and is higher than any of melting points TL1, TM1 of fourth laminate 44 of circuit board 401 and conductive via 81a of fifth laminate 45.

First laminate 41 and conductive via 80a of top circuit board 400, fourth laminate 44 of circuit boards 401 to 4n, and conductive via 81a may be formed of, for example, aluminum or a material other than copper, such as an aluminum material obtained by adding an additive to aluminum.

### <Manufacturing Method>

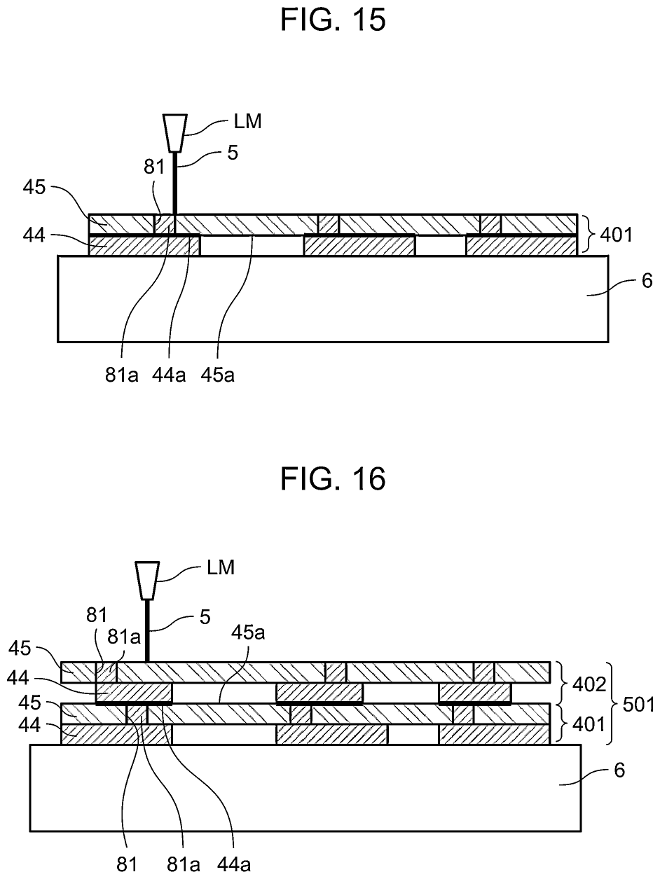

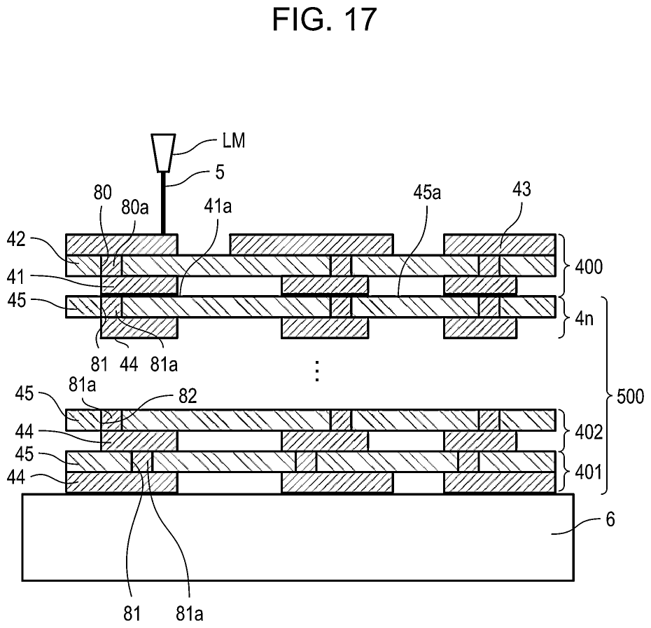

Next, a method for manufacturing laminated structure 4 will be described. FIG. 14 is a diagram illustrating fourth laminate 44 in which through hole 81 is formed. FIG. 15 is a diagram illustrating a step of forming fourth laminate 44 on fifth laminate 45. FIG. 16 is a diagram illustrating a step of joining circuit board 401 and circuit board 402. FIG. 17 is a diagram illustrating a process of joining top circuit board 400 to multiple structure 500.

### (1) Formation of Circuit Boards 401 to 4n

First, through hole 81 is formed in fifth laminate 45 (see FIG. 14). For example, through hole 81 may be formed by laser processing, machining, or the like.

Next, fourth laminate 44 is formed on main surface 45a of fifth laminate 45. This step is the same as the step of forming third laminate 33 that is a circuit pattern on second laminate 32 in the third exemplary embodiment.

In the fourth exemplary embodiment, when surface portion 44a of fourth laminate 44 having a plate shape on fifth laminate 45 side melts through irradiation with laser light 5, melted surface portion 44a enters through hole 81. Thereafter, the temperature decreases, and surface portion 44a becomes a solid state, whereby conductive via 81a is formed (see FIG. 15).

Before the step of forming fourth laminate 44, conductive via 81a may be formed inside through hole 81 of fifth laminate 45 in a step different from the step.

Through the above steps, circuit board 401 is formed. The circuit boards 402 to 4n are also formed in the same manner. The material of fourth laminate 44 of circuit boards 401 to 4n is selected so as to satisfy the above relationship (1).

### (2) Formation of Multiple Structure 500

As illustrated in FIG. 16, circuit board 401 is placed on table 6 such that fourth laminate 44 is in contact with table 6. Then, circuit board 402 is placed on circuit board 401 with fourth laminate 44 being aligned to be in contact with conductive via 81a of fifth laminate 45 of circuit board 401.

Next, laser light 5 is emitted from fifth laminate 45 side of circuit board 402 in a state where fourth laminate 44 of circuit board 402 is pressed against fifth laminate 45 of circuit board 401. In laser emission device LM, the intensity of laser light 5 is set to such an extent that only fourth laminate 44 of circuit board 402 melts out of fourth laminate 44 and fifth laminate 45 of circuit boards 401, 402.

Fifth laminate 45 of circuit board 402 is heated by laser light 5. The heat generated in fourth laminate 44 is transmitted to fourth laminate 44 of circuit board 402. Fifth laminate 45, having a larger absorptivity with respect to laser light 5 than fourth laminate 44, easily generates heat.

In addition, since melting point TL2 of fourth laminate 44 of circuit board 402 is lower than the melting point of fifth laminate 45 of circuit board 402, fourth laminate 44 melts but fifth laminate 45 does not melt. Then, surface portion 44a of fourth laminate 44 enters the recess formed in main surface 45a of fifth laminate 45 of circuit board 401. Thereafter, surface portion 44a of fourth laminate 44 is brought into a solid state with a decrease of the temperature, and surface portion 44a of fourth laminate 44 of circuit board 402 meshes with the irregular portion of main surface 45a of fifth laminate 45 of circuit board 401. As a result, fifth laminate 45 of circuit board 401 and fourth laminate 44 of circuit board 402 are joined to form laminated portion 501.

Next, laminated portion 501 and circuit board 403 are joined. Here, fifth laminate 45 of circuit board 402 and fourth laminate 44 of circuit board 403 are joined. Details are the same as the joining between circuit board 401 and circuit board 402.

In the same manner, circuit boards 404 to 4n are sequentially joined to circuit boards 403 to 4n-1 to form multiple structure 500.

### (3) Formation of Top Circuit Board 400

Through hole 80 is formed in second laminate 42, and conductive via 80a is formed inside through hole 80.

Next, third laminate 43 formed of the same material as conductive via 80a is formed as a circuit pattern on main surface 42a of second laminate 42, and first laminate 41 is formed as a circuit pattern on main surface 42b.

The step of forming third laminate 43 is the same as the step of forming fourth laminate 44 as a circuit pattern on fifth laminate 45 in the present exemplary embodiment except that conductive via 80a is not formed. The step of forming fourth laminate 44 is the same as the step of forming third laminate 33 on second laminate 32 in the third exemplary embodiment.

### (4) Joining of Multiple Structure 500 and Top Circuit Board 400

First, as illustrated in FIG. 17, top circuit board 400 is placed on multiple structure 500 placed on table 6. Here, first laminate 41 of top circuit board 400 is placed on fifth laminate 45 of circuit board 4n while being aligned so as to be in contact with conductive via 81a of fifth laminate 45.

Next, in a state where first laminate 41 of top circuit board 400 is pressed against fifth laminate 45 of circuit board 4n, laser light 5 is emitted from third laminate 43 side of top circuit board 400. In laser emission device LM, the intensity of laser light 5 is set to such an extent that only first laminate 41 of top circuit board 400 melts out of laminates 41 to 45.

Second laminate 42 and third laminate 43 of top circuit board 400 are heated by laser light 5. The heat generated in second laminate 42 and third laminate 43 is transmitted to third laminate 43. Second laminate 42, having a larger absorptivity with respect to laser light 5 than first laminate 41, easily generates heat.

In addition, melting point T41 of first laminate 41 of top circuit board 400 is lower than melting points of second laminate 42 of top circuit board 400 and fifth laminate 45 of circuit board 4n. Thus, first laminate 41 melts but second laminate 42 and fifth laminate 45 on both sides of first laminate 41 of top circuit board 400 do not melt. Then, surface portion 41a of melted first laminate 41 enters the recess formed in main surface 45a of fifth laminate 45 of circuit board 4n. Thereafter, as the temperature decreases, surface portion 41a becomes a solid state, and the surface portion meshes with the irregular portion of fifth laminate 45 of circuit board 4n. As a result, multiple structure 500 and top circuit board 400 are joined. Laminated structure 4 is thus formed.

The materials of top circuit board 400 and conductive vias 80a, 81a of circuit board 4n are not necessarily limited as long as the melting points of top circuit board 400 and conductive vias 80a, 81a of circuit board 4n satisfy the relationship represented by Formula (2) or (3) shown below. That is, conductive via 80a of top circuit board 400 is not necessarily formed of the same material as first laminate 41, and conductive via 81a of circuit boards 401 to 4n is not necessarily formed of the same material as fourth laminate 44 in the same circuit board.

$$T 42 > TL 1 > TM 1 > TL 2 > TM 2 > … > TLn > TMn > T 41 \qquad ( 2 )$$

$$T 42 > TM 1 > TL 1 > TM 2 > TL2 > … > TMn = TMn > T 41 \qquad ( 3 )$$

In this case, when circuit boards 401 to 4n are formed, conductive via 81a is formed before the step of forming third laminate 43 on second laminate 42.

In the present exemplary embodiment, first laminate 41 and third laminate 43 are circuit patterns, and second laminate 42 is formed with conductive via 80a connecting first laminate 41 and third laminate 43.

First laminate 41 is laminated on multiple structure 500 formed by laminating a plurality of circuit boards 401 to 4n formed by sequentially laminating fourth laminate 44 and fifth laminate 45. Each of the plurality of fourth laminates 44 has a melting point lower than the melting point of any of second laminate 42 and the plurality of fifth laminates 45, and fourth laminate 44 among the plurality of fourth laminates 44 whose disposed position is closer to second laminate 42 has a lower melting point.

Thus, laminated structure 4 functions as an electric circuit board having a multilayer structure. In addition, since fourth laminate 44 among the plurality of fourth laminates 44 closer to second laminate 42 of the top circuit board 400 has a lower melting point, a multilayer circuit board in which a large number of circuit boards are laminated can be easily produced using laser light 5.

Second laminate 42 and third laminate 43 are welded such that conductive via 80a disposed in through hole 80 formed in second laminate 42 is connected to third laminate 43. The laminates on both surfaces of second laminate 42 can be thus electrically connected.

In the method for manufacturing laminated structure 4 according to the present exemplary embodiment, circuit boards 401 to 4n in which fourth laminate 44 having a melting point lower than that of third laminate 43 and higher than that of first laminate 41, and fifth laminate 45 are sequentially laminated is formed. Then, top circuit board 400 including first laminate 41, second laminate 42, and third laminate 43 is placed on circuit board 4n such that first laminate 41 is in contact with fifth laminate 45. Further, irradiating surface portion 41a of first laminate 41 with laser light 5 from third laminate 43 side melts surface portion 41a and makes melted surface portion 41a enter the recess formed in main surface 45a of the fifth laminate 45.

Thus, in the multilayer circuit board, the circuit boards can be welded to each other with a wide adhesion area and high adhesion.

In the laminated structure of the present disclosure, at least three laminates are laminated, and the melting point of the laminate disposed in the middle among the three laminates is higher than the melting points of the other laminates. In the exemplary embodiments, it has been described that the laminate disposed at the center among the three laminates is formed of an insulating material, and the laminates on both sides are formed of a conductive material. However, all the laminates may be formed of an insulating material or a conductive material.

The present disclosure also includes a mode obtained by making various modifications conceivable by those skilled in the art to each of the exemplary embodiments and modifications, and a mode obtained by combining any components and any functions in each of the exemplary embodiments without departing from the gist of the present disclosure.

The present disclosure can provide a laminated structure and a method for manufacturing the laminated structure that can easily manufacture a laminated structure in which a plurality of members are laminated with a small number of devices.

### INDUSTRIAL APPLICABILITY

The present disclosure can be suitably applied to a laminated structure in which an insulating substrate and a conductor layer are welded and a method for manufacturing the laminated structure. For example, the laminated structure can be applied for a heat dissipation device, a semiconductor device, and an electric circuit board.

### REFERENCE MARKS IN THE DRAWINGS

1: laminated structure
1A: laminated portion
2: laminated structure
2A: laminated portion
3: laminated structure
3A: laminated portion
3B: laminated portion
3C: laminated portion
4: laminated structure
4n: circuit board
4n-1: circuit board
5: laser light
6: table
11: first laminate
11a: surface portion
12: second laminate
12a: main surface
12b: main surface
13: third laminate
13a: surface portion
21: first laminate
21a: surface portion
21f: fin
22: second laminate
22b: main surface
23: third laminate
31: first laminate
32: second laminate
32a: main surface
33: third laminate
33a: surface portion
33e: pattern region
33p: pattern portion
41: first laminate
41a: surface portion
42: second laminate
42a: main surface
42b: main surface
43: third laminate
44: fourth laminate
44a: surface portion
45: fifth laminate
45a: main surface
45b: main surface
80: through hole
80a: conductive via
81: through hole
81a: conductive via
400: top circuit board
401: circuit board
402: circuit board
403: circuit board
404: circuit board
500: multiple structure
501: laminated portion
LM: laser emission device

1. A laminated structure comprising:
a first laminate;
a second laminate; and
a third laminate, wherein
the first laminate, the second laminate, and the third laminate being sequentially laminated,
melting points of the first laminate, the second laminate, and the third laminate are different from each other, and
the melting point of the second laminate is higher than the melting point of any of the first laminate and the third laminate.

2. The laminated structure according to claim 1, wherein
the first laminate comprises a first conductive material,
the second laminate comprises an insulating material, and
the third laminate comprises a third conductive material.

3. The laminated structure according to claim 2, wherein
the first melting point is lower than the third melting point, and
the first laminate includes a heat dissipation structure.

4. The laminated structure according to claim 1, wherein the third laminate is a circuit pattern.

5. The laminated structure according to claim 4, wherein
the first laminate is a circuit pattern, and
the second laminate includes a conductive via connecting the first laminate and the third laminate.

6. The laminated structure according to claim 5, wherein
the first laminate is laminated on a multiple structure, the multiple structure including a plurality of laminated circuit boards, each of the circuit boards including a fourth laminate and a fifth laminate laminated on the fourth laminate, and
each of a plurality of the fourth laminates has a melting point lower than a melting point of any of the second laminate and a plurality of the fifth laminates, and a fourth laminate among the plurality of fourth laminates whose disposed position is closer to the second laminate has a lower melting point.

7. The laminated structure according to claim 1, wherein the second laminate comprises aluminum nitride ceramic.

8. The laminated structure according to claim 1, wherein the third laminate has an absorptivity with respect to laser light in a predetermined wavelength band larger than an absorptivity of the first laminate with respect to the laser light in the predetermined wavelength band.

9. The laminated structure according to claim 8, wherein the predetermined wavelength band is more than or equal to 400 nm and less than or equal to 600 nm.

10. The laminated structure according to claim 1, wherein the first laminate and the third laminate comprise copper materials having different melting points.

11. The laminated structure according to claim 1, wherein
the first laminate comprises an aluminum material, and
the third laminate comprises a copper material.

12. A method for manufacturing a laminated structure formed by sequentially laminating a first laminate, a second laminate, and a third laminate, the method comprising:
placing the second laminate on the third laminate; and
irradiating a surface portion of the third laminate on the second laminate side with laser light from the second laminate side to melt the surface portion of the third laminate on the second laminate side, and allowing the surface portion that has been melted to enter a recess formed in a surface of the second laminate on the third laminate side.

13. The method according to claim 12, further comprising:
placing a laminated portion including the second laminate and the third laminate on the first laminate to allow the second laminate to be in contact with the first laminate; and
irradiating a surface portion of the first laminate on the second laminate side with the laser light from the third laminate side to melt the surface portion of the first laminate on the second laminate side, and allowing the surface portion that has been melted to enter a recess formed in a surface of the second laminate on the first laminate side.

14. The method according to claim 13, wherein the first laminate includes a heat dissipation structure.

15. The method according to claim 12, comprising welding the second laminate and the third laminate to allow a conductive via disposed in a through hole formed in the second laminate to be connected to the third laminate.

16. The method according to claim 15, further comprising:
forming a circuit board formed by sequentially laminating a fourth laminate having a melting point lower than a melting point of the third laminate and higher than a melting point of the first laminate, and a fifth laminate;
placing a laminated portion including the first laminate, the second laminate, and the third laminate on the circuit board to allow the first laminate to be in contact with the fifth laminate; and
irradiating a surface portion of the first laminate on the fifth laminate side with laser light from the third laminate side to melt a surface portion of the first laminate on the fifth laminate side, and allowing the surface portion that has been melted to enter a recess formed in a surface of the fifth laminate on the first laminate side.

17. The method according to claim 12, further comprising irradiating the third laminate with the laser light to remove a part of the third laminate and form the third laminate into a predetermined circuit pattern.

18. The method according to claim 12, wherein the laser light has a wavelength band of more than or equal to 400 nm and less than or equal to 600 nm.
